(19) United States
(12) Patent Application Publication
(10) Pub. No.: US 2012/0253542 A1
(43) Pub. Date: Oct. 4, 2012

(54) Method and apparatus for temperature measurement on a display backlight

(75) Inventors: Juha Harri-Pekka Nurmi, Salo (FI); Jani Edvin Penttila, Lempaala (FI)

(73) Assignee: Nokia Corporation

(21) Appl. No.: 13/065,913

(22) Filed: Apr. 1, 2011

(51) Int. Cl. G05D 23/19; G09G 3/32; G06F 3/038; H03K 3/00; H05B 37/00

(52) U.S. Cl. 700/299; 327/108; 315/185 R; 345/204; 345/82

(57) ABSTRACT

In accordance with an example embodiment of the present invention, an apparatus is disclosed. The apparatus includes a driver, a set of first components, a set of second components, a third component, and a switch. The driver includes a first output and a second output. The set of first components is connected to the first output of the driver. The set of first components are connected in series. The set of second components are connected to the second output of the driver. The set of second components are connected in series. The third component is connected in parallel with the set of second components. The switch is connected in parallel with the set of second components. The switch is between the third component and the second output of the driver. The switch is configured to be controlled by the first output of the driver.

### TECHNICAL FIELD

The invention relates to a display backlight and, more particularly, to temperature measurement for a display backlight.

### BACKGROUND

As electronic devices continue to become more sophisticated, these devices provide an increasing amount of functionality by including such applications as, for example, a mobile phone, digital camera, video camera, navigation system, gaming capabilities, and internet browser applications. With this increasing amount of functionality, device displays and display backlights have become increasingly important in providing a better user experience which can take full advantage of the capabilities of mobile device.

Accordingly, as consumers demand increased functionality from electronic devices, there is a need to provide improved devices having increased capabilities, while maintaining robust and reliable product configurations.

### SUMMARY

Various aspects of examples of the invention are set out in the claims.

According to a first aspect of the present invention, an apparatus is disclosed. The apparatus includes a driver, a set of first components, a set of second components, a third component, and a switch. The driver includes a first output and a second output. The set of first components is connected to the first output of the driver. The set of first components are connected in series. The set of second components are connected to the second output of the driver. T set of second components are connected in series. The third component is connected in parallel with the set of second components. The switch is connected in parallel with the set of second components. The switch is between the third component and the second output of the driver. The switch is configured to be controlled by the first output of the driver.

According to a second aspect of the present invention, a method is disclosed. A first set of series connected light sources are connected to a first output of a driver. A second set of series connected light sources are connected to a second output of the driver. A switch and a component are connected in parallel with the second set of light sources. The switch is configured to be controlled by the first output of the driver. The component is connected to the second output of the driver.

According to a third aspect of the present invention, an apparatus is disclosed. The apparatus includes at least one processor, and at least one memory. The at least one memory includes computer program code. The at least one memory and the computer program code configured to, with the at least one processor, cause the apparatus to perform at least the following. Control a switch with a first output of a driver. Adjust output currents at the first output of the driver and a second output of the driver in response to a measurement of a temperature sensor. The temperature sensor is connected to the second output of the driver. Energize a first set and a second set of light sources in an impulse mode. The first set of light sources is connected to the first output. The second set of light sources is connected to the second output.

### BRIEF DESCRIPTION OF THE DRAWINGS

For a more complete understanding of example embodiments of the present invention, reference is now made to the following descriptions taken in connection with the accompanying drawings in which:

FIG. 1 is a front view of an electronic device incorporating features of the invention;

FIG. 2 is a perspective view illustrating components of the device shown in FIG. 1;

FIG. 3 is top view illustrating components of the device shown in FIG. 1;

FIG. 4 is a top view of a display module used in the device shown in FIG. 1;

FIG. 5 is a section view of the display module shown in FIG. 4;

FIG. 6 is a schematic drawing illustrating components of the device shown in FIG. 1;

FIG. 7 is a configuration table corresponding to the schematic drawing shown in FIG. 6;

FIG. 8 is a schematic drawing illustrating components of the device shown in FIG. 1;

FIG. 9 is a configuration table corresponding to the schematic drawing shown in FIG. 8;

FIG. 10 is a graphical representation corresponding to the schematic drawing shown in FIG. 8;

FIG. 11 is an schematic drawing illustrating components of the device shown in FIG. 1;

FIG. 12 is an exemplary simulation result for the schematic diagram shown in FIG. 11;

FIG. 13 is another exemplary simulation result for the schematic diagram shown in FIG. 11;

FIG. 14 is another schematic drawing illustrating components of the device shown in FIG. 1;

FIG. 15 is another schematic drawing illustrating components of the device shown in FIG. 1;

FIG. 16 is a configuration table corresponding to the schematic drawing shown in FIG. 15;

FIG. 17 is a block diagram of an exemplary method of the device shown in FIG. 1;

FIG. 18 is a graphical representation of temperature and current o a light source used in the device shown in FIG. 1;

FIG. 19 is another schematic drawing illustrating components of the device shown in FIG. 1;

FIG. 20 is a block diagram of an exemplary method of the device shown in FIG. 1;

FIG. 21 is a configuration table corresponding to the schematic drawing shown in FIG. 19;

FIG. 22 is another schematic drawing illustrating components of the device shown in FIG. 1;

FIG. 23 is another schematic drawing illustrating components of the device shown in FIG. 1;

FIG. 24 is a block diagram of an exemplary method of the device shown in FIG. 1; and

FIG. 25 is a schematic drawing illustrating components of the device shown in FIG. 1.

### DETAILED DESCRIPTION OF THE DRAWINGS

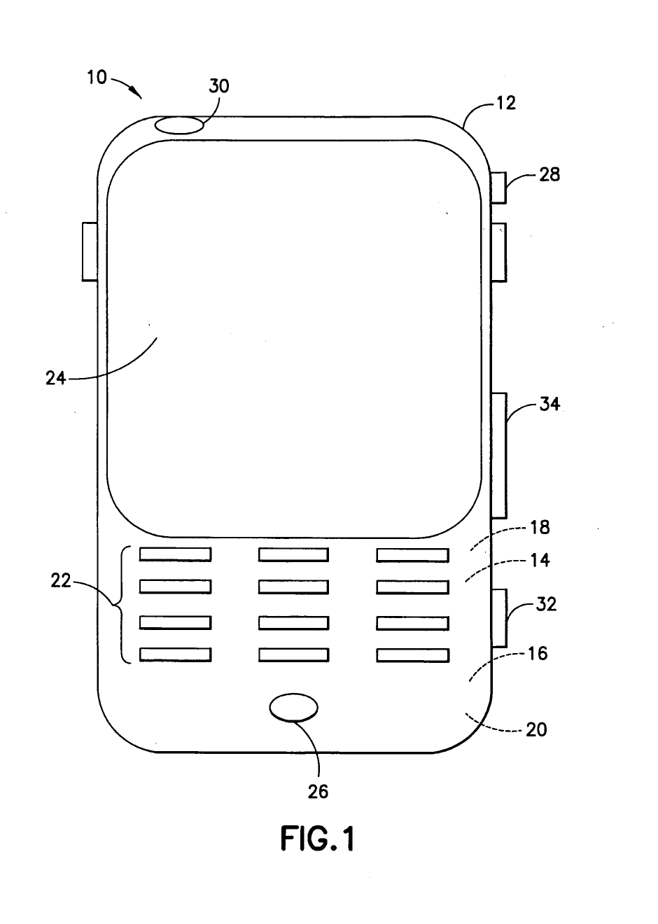

An example embodiment of the present invention and its potential advantages are understood by referring to FIGS. 1 through 25 of the drawings.

Referring to FIG. 1, there is shown a front view of an electronic device 10 incorporating features of the invention. Although the invention will be described with reference to the exemplary embodiments shown in the drawings, it should be understood that the invention can be embodied in many alternate forms of embodiments. In addition, any suitable size, shape or type of elements or materials could be used.

According to one example of the invention, the device 10 is a multi-function portable electronic device. However, in alternate embodiments, features of the various embodiments of the invention could be used in any suitable type of portable electronic device such as a mobile phone, a gaming device, a music player, a notebook computer, or a personal digital assistant, for example. In addition, as is known in the art, the device 10 can include multiple features or applications such as a camera, a music player, a game player, or an Internet browser, for example. The device 10 generally comprises a housing 12, a transmitter 14, a receiver 16, an antenna 18 (connected to the transmitter 14 and the receiver 16), electronic circuitry 20, such as a controller (which could include a processor, for example) and a memory for example, within the housing 12, a user input region 22 and a display 24. The display 24 could also form a user input section, such as a touch screen.

The device (or user equipment) 10 may further comprise voice-recognition technology received at the microphone 26. Additionally, a power actuator 28 controls the device being turned on and off by the user. The exemplary device 10 may have a camera 30 which is shown as being forward facing (for example, for video calls) but may alternatively or additionally be rearward facing (for example, for capturing images and video for local storage). The camera 30 is controlled by a shutter actuator 32 and optionally by a zoom actuator 34 which may alternatively function as a volume adjustment for a speaker of the device when the camera 30 is not in an active mode. It should be noted these are provided as exemplary non-limiting features and that in alternate embodiments, the device 10 can have any suitable type of features as known in the art.

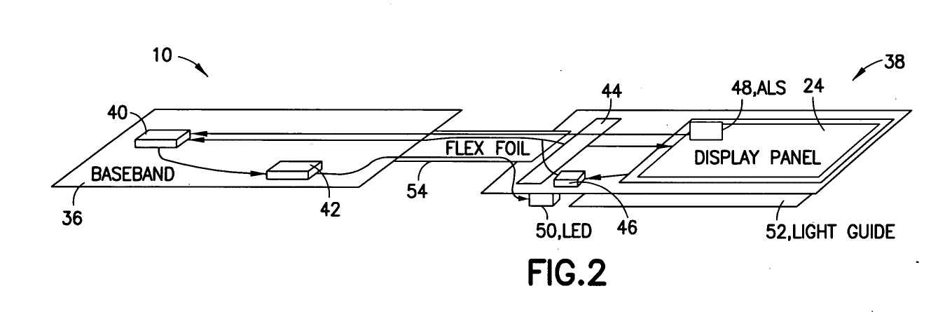

Referring now also to FIGS. 2 and 3, wherein FIG. 2 is a perspective view illustrating components of the device 10, and FIG. 3 is a schematic drawing of the illustrated device components. In particular, there is shown a base band 36 and a display module 38. The base band 36 generally includes an engine 40, and a backlight controller 42. The engine 40 generally controls various conversions of the device 10, such as converting electrical information to a readable format on the display 24, or converting audio from acoustic waves to an electrical format, for example. The engine 40 can include a controller (which could include a processor, for example). In various exemplary embodiments of the invention the engine 40 also controls the backlight controller 42. Additionally, according to some embodiments of the invention, more than one engine could be provided.

The display module 38 generally includes the display panel 24 (which as mentioned above, could include a touch screen), a display driver 44, a touch screen controller 46, an ambient light sensor (ALS) 48, a light emitting diode (LED) arrangement 50, and a light guide 52. The display driver 44 may, for example, generate VCOM, timings, and send panel control and image information to the display panel 24. The ALS 48 may be connected to the engine 40 and can include any suitable type of component configured for converting ambient light to electrical information. According to various exemplary embodiments the engine 40 generally controls the image of the display panel 24 and can also read touch screen values via the touch screen controller 46. The engine 40 can also control the backlight controller 42 to control the backlight (such as controlling the light emitting diode arrangement 50). According to some embodiments of the inventions the ALS 48 can be integrated on the display panel 24 and the information may be transferred to the engine 40. However, any suitable configuration may be provided.

According to some embodiments of the invention, a flex foil (or flexible printed circuit) 54 may be connected between the base band 36 and the display module 38. In this embodiment, a multipoint connection 56 is provided between the engine 40, the display driver 44, and touch screen controller 46. However, in alternate embodiments, any suitable type, or number, of connections may be provided. It should further be noted that the components described above are provided as non-limiting examples and any suitable configurations for the base band and the display module can be provided.

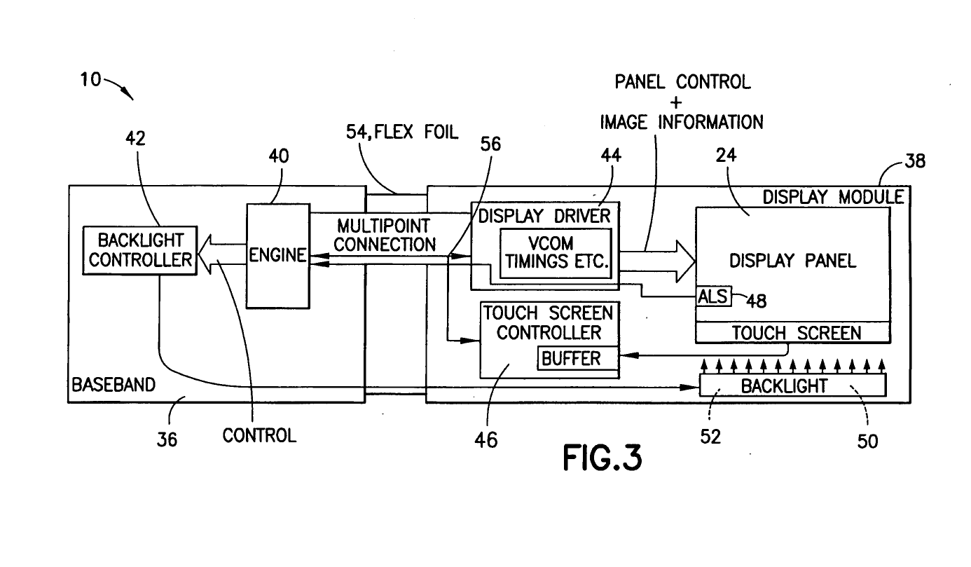

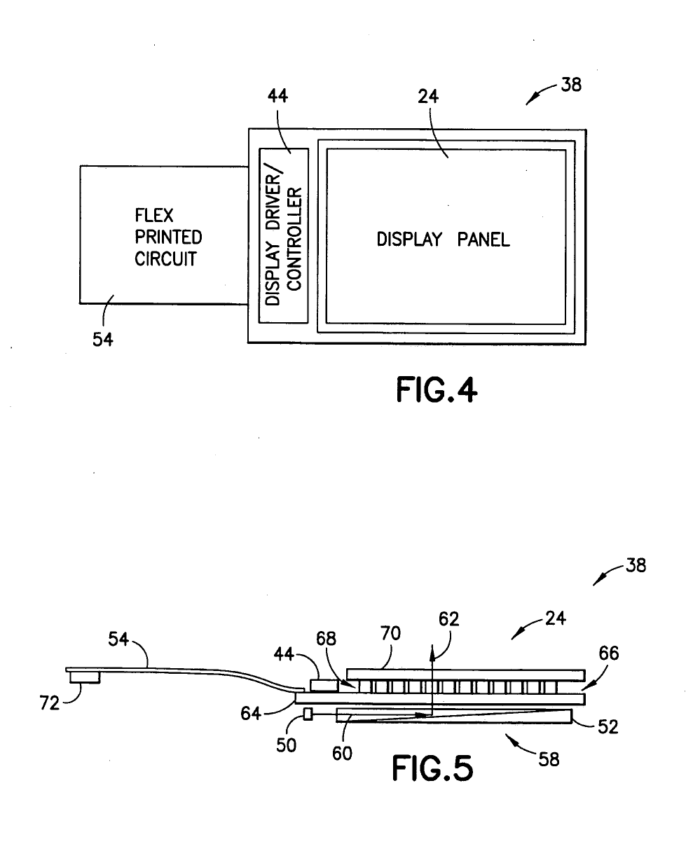

Referring now also to FIGS. 4 and 5, the display module 38 is shown in further detail. As described above, the display module 38 includes the display panel 24 (controlled by the display driver integrated circuit 44). The display panel 24 can be, for example, a liquid crystal display (LCD) panel. However, in alternate embodiments, any suitable type of display panel may be provided. As shown in FIG. 5, the light emitting diode arrangement 50 is provided as a source of illumination for the display panel 24. Additionally, the light guide 52 is used to transfer the light from the light source 50 to the display panel 24 (to illuminate the display panel). In this embodiment, the light guide 52 comprises a prism sheet 58. However, in alternate embodiments different kinds of prism sheets can be implemented under the display panel and the light guide to improve the illumination uniformity of the display panel.

Arrows 60, 62 are provided for illustrating the path of light from the LED arrangement 50 and through the various components. For example, in this embodiment, the light travels through the light guide 52 (and the prism sheet 58), a bottom glass 64, liquid crystal material 66 (and color filters 68), and an upper glass 70. However, in alternate embodiments any suitable configuration may be provided.

In this embodiment of the invention, one end of the flex foil (or flex printed circuit) 54 is coupled to the display module, and the other end comprises a connector 72 configured to be connected to the baseband 36. However, in alternate embodiments, any suitable type, or number, of connections may be provided. Additionally, any other suitable type of display components may be provided.

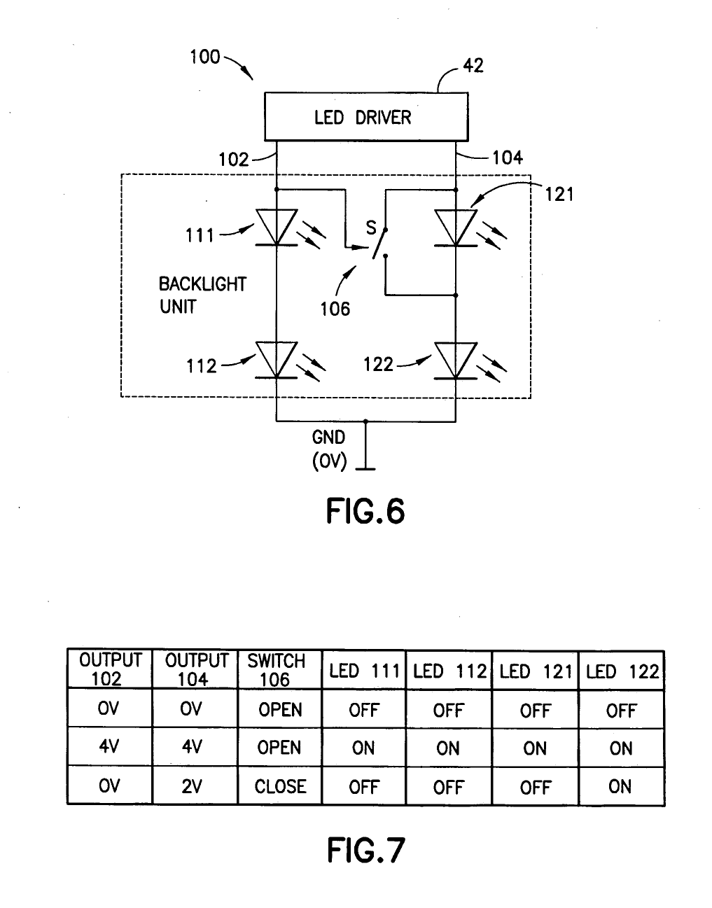

Referring now also to FIG. 6, there is shown a schematic drawing of an example backlight LED connection configuration (or backlight arrangement) 100 according to one example of the invention. The backlight LED connection configuration 100 includes the LED driver (or backlight controller) 42 and light emitting diodes 111, 112, 121, 122 of the LED arrangement 50. The LED driver comprises a first output 102 and a second output 104. The LED connections are controlled by the LED driver (which may be an integrated circuit, for example) 42. In this embodiment, the LED chains are connected in parallel, wherein each chain includes two LEDs connected in series. For example, one chain of series connected LEDs includes LED 111 and LED 112, and the other chain of series connected LEDs includes LED 121 and LED 122. However, in alternate embodiments any suitable number of LEDs or configuration may be provided.

The backlight LED connection configuration 100 also includes a switch 106 (which may be a Field-Effect Transistor [FET], for example) connected in parallel with the light source (LED) 121. However, it should be noted that in some embodiments, the switch 106 may instead be connected in parallel with the light source (LED) 122. According to some embodiments of the invention, the switch 106 can be controlled by one of the other LED driving outputs (such as the first output 102). Additionally, in this embodiment, the switch 106 can bypass the light source when the switch 106 is closed. According to various exemplary embodiments of the invention the switch configuration can be used to change illumination of the backlight of the LCD panel, or keyboard, for example, such as for reduced power consumption (as in an LCD low power mode, for example). One advantage with the switch configuration is that an additional control line from the LED driver (as may be found in some conventional configurations) is generally not needed to select another configuration of the light sources in the serial and parallel chains.

Referring now also to FIG. 7, there is shown a configuration table for the exemplary backlight LED connection 100 shown in FIG. 6. The table shows if the LEDs 111, 112, 121, 122, are “On” (LED is illuminating light) or “Off” (LED not emitting light) based on the LED driver outputs 102, 104 and the switch 106 position.

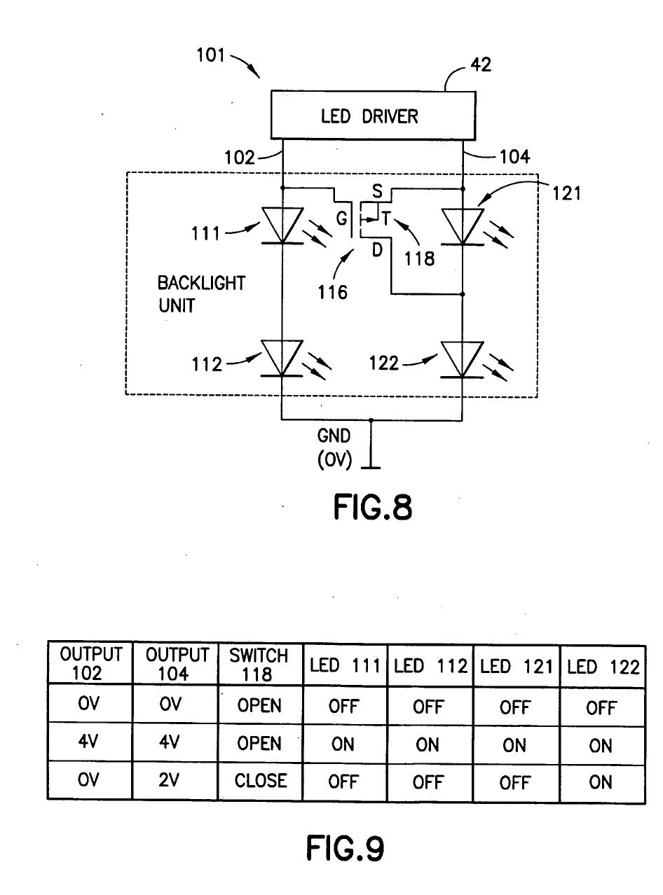

Referring now also to FIG. 8, there is shown a schematic drawing of an example backlight LED connection configuration (or backlight arrangement) 101 according to another example of the invention. The backlight LED connection configuration 101 is similar to the backlight LED connection configuration 100 and similar features are similarly numbered. The backlight LED connection configuration 101 includes the LED driver 42 and the LEDs 111, 112, 121, 122. However, in this embodiment the backlight LED connection configuration 101 includes a p-type metal-oxide-semiconductor field-effect transistor (MOSFET) 116 connected in parallel with the light source 121. However, in some embodiments the p-type MOSFET may be connected in parallel with the LEDs 121, 122. According to some embodiments of the invention, the MOSFET comprises a switch portion 118. According to some embodiments of the invention, the switch can be controlled by the LED driving outputs 102. Similarly, this configuration can provide for changing a configuration of the light sources 111, 112, 121, 122 to change illumination of the backlight of the LCD panel, or keyboard.

Referring now also to FIG. 9, there is shown a configuration table for the exemplary backlight LED connection 101 shown in FIG. 8. The table shows if the LEDs 111, 112, 121, 122, are “On” (LED is illuminating light) or “Off” (LED not emitting light) based on the LED driver outputs 102, 104 and the transistor switch 118 position.

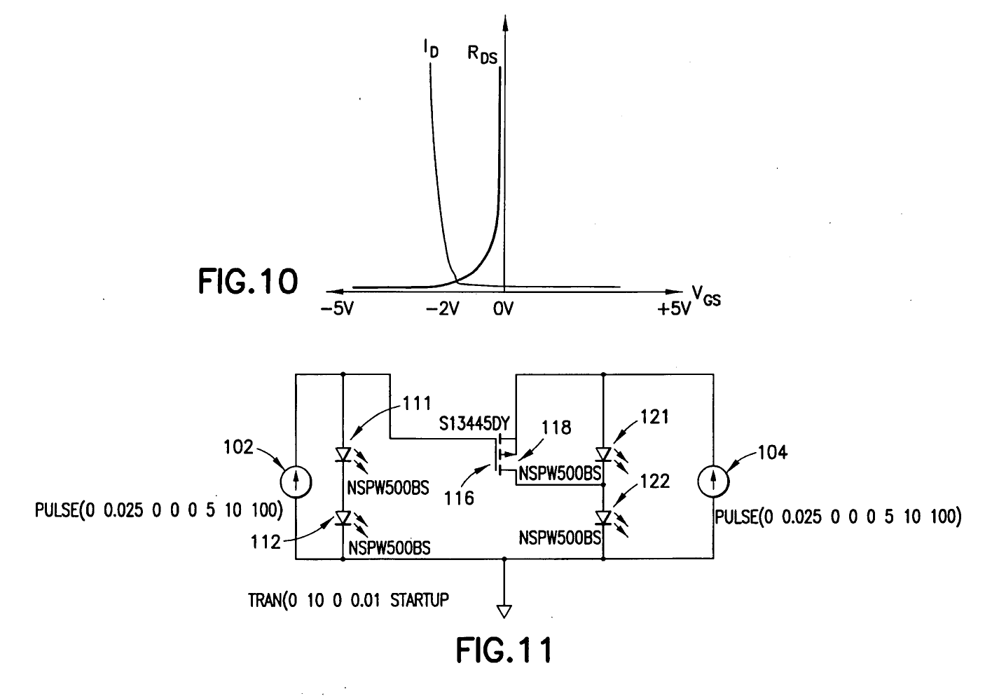

For example, and referring now also to FIG. 10, the VGS of the transistor 116 is −2.0V, when the first output 102 is low (0V) and the second output 104 is high (+2V) [first output 102 is lower than the second output 104] then the transistor switch 118 is closed (current can flow from S-to-D) and the LED 121 is bypassed. The Vgs of the transistor 116 is generally 0V when the first output 102 and the second output 104 are equal (0V, 2V or 4V) then the transistor switch 118 is open (current cannot flow from S-to-D) and the LED 121 is not bypassed.

Referring now also to FIG. 11, there is shown a backlight simulation for the backlight arrangement 101. In this simulation, for the purposes of clarity, the LED driver 42 is represented by only illustrating the first output 102 and the second output 104. In this embodiment, the p-type MOSFET 116 may be an SI3445DV device for example. However in alternate embodiments, any suitable type of field effect transistor may be provided. In this simulation, the LEDs 111, 112, 121, 122 are connected in substantially the same configuration as is FIG. 8. In this simulation, the current sources 102, 104 are turned on and off simultaneously (On 5 s-Off 5 s).

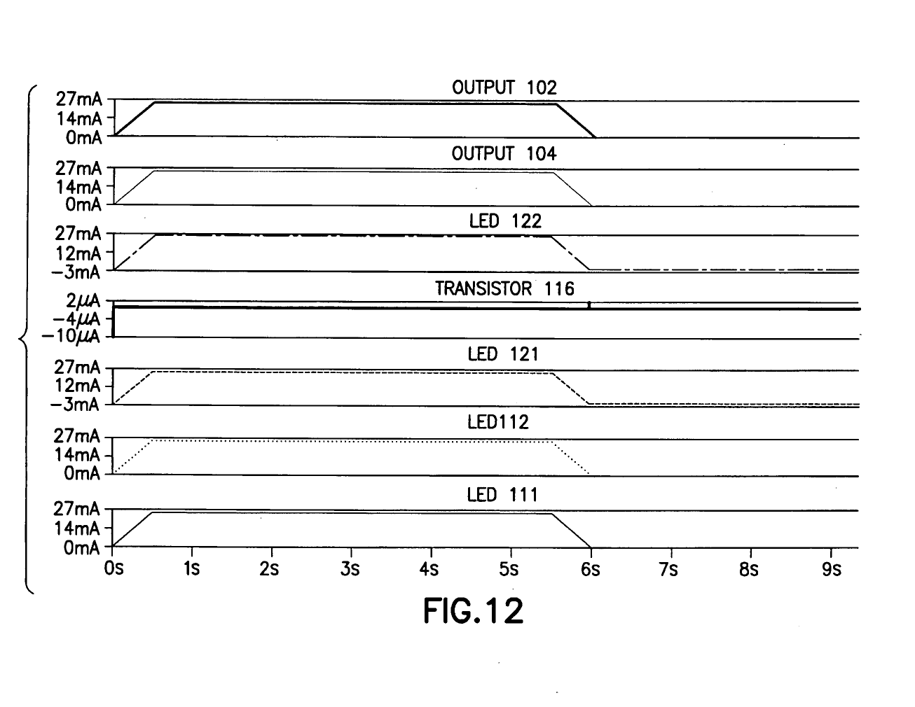

The simulation result (illustrated in FIG. 12) shows that all of the LEDs 111, 112, 121, 122 are illuminating light (around 5 s). All of the LEDS 111, 112, 121, 122 are off (around 5 s). There is no current flow via the transistor 116.

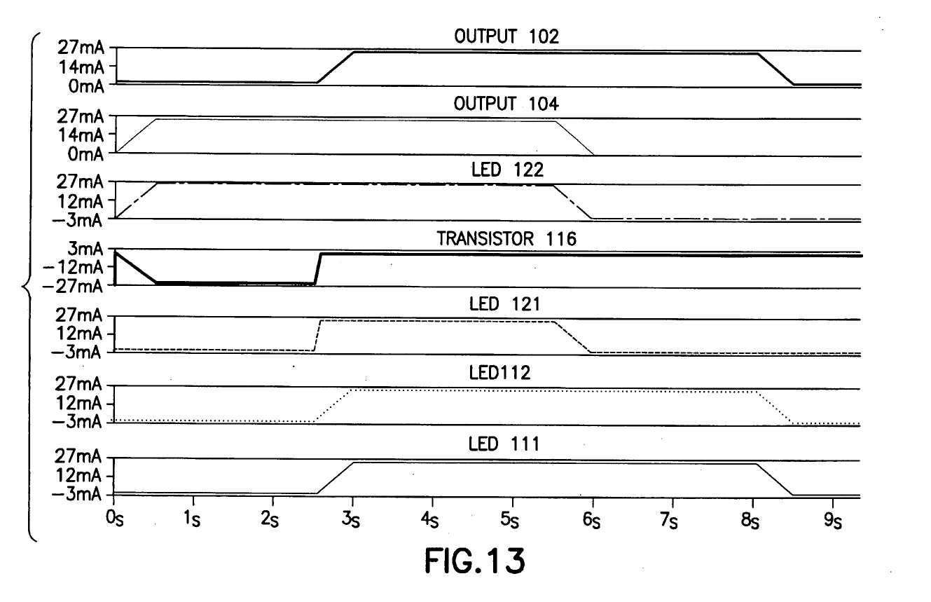

Referring now also to FIG. 13, there is shown another simulation result where, similar to the results in FIG. 12, the current sources 102, 104 are turned on and off (On 5 s-Off 5 s), however in this example the first output 102 is delayed 2.5 s. This simulation result is that the LED 122 (Low Power Mode) is illuminating light and the LED 121 is passed via the transistor 116 (see currents for the transistor 116 and the LED 121), (around 2.5 s). All of the LEDs 111, 112, 121, 122 are illuminating light (around 2.5 s). Two of the LEDs (111 and 112) are illuminating light (around 2.5 s). All of the LEDs 111, 112, 121, 122 are off.

While various exemplary embodiments of the invention have been described in connection with two parallel chains, one skilled in the art will appreciate that embodiments of the invention are not necessarily so limited and that optional configurations are also possible that are based on any suitable number of parallel chains.

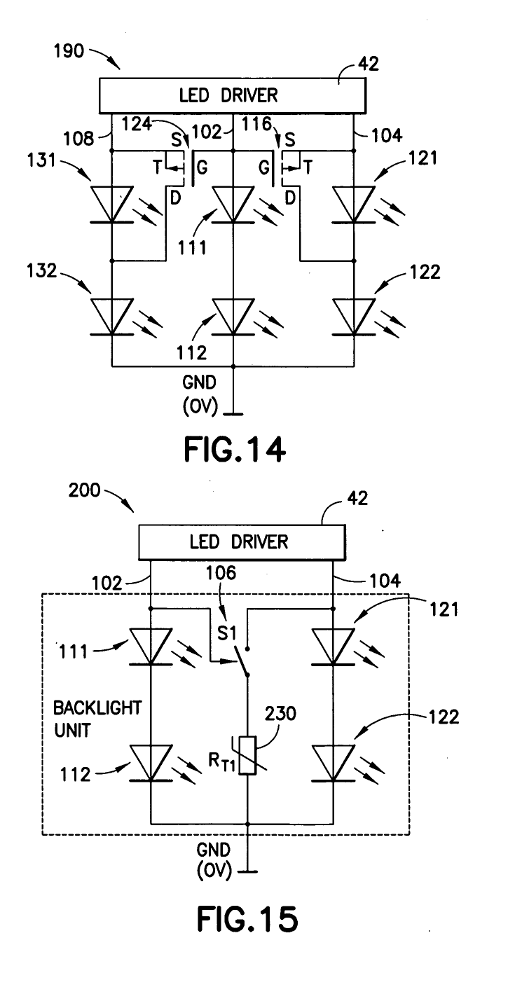

For example, and referring now also to FIG. 14, there is shown a schematic drawing of an example backlight LED connection configuration (or backlight arrangement) 190 according to another example of the invention. Similar to the backlight arrangement 100, 101, the backlight LED connection configuration 190 includes the LED driver (or backlight controller) 42, the LEDs 111, 112, 121, 122, and the transistor 116. The LED connections are controlled by the LED driver 42. However, in this embodiment there are three LED chains connected in parallel, wherein each chain includes two LEDs connected in series.

For example in this embodiment, the backlight LED connection configuration further includes a third driver output 108, two series connected LEDs 131, 132, and another p-type MOSFET 124 connected in parallel with the light source 131. According to some embodiments of the invention, the output difference at 108 and 102 controls the transistor 124. This configuration can also provide for changing a configuration of the light sources to change illumination of the backlight of the LCD panel, or keyboard.

Without in any way limiting the scope, interpretation; or application of the claims appearing below, a technical effect of one or more of the example embodiments disclosed herein is that a backlight (LED driver) can be used to drive only a single LED, for example in a linear mode directly from the battery to achieve really low power. Another technical effect of one or more of the example embodiments disclosed herein is that a switching converter function is not needed, to boost up the voltage, and efficiency of the system will increase. Another technical effect of one or more of the example embodiments disclosed herein is that no additional components (in addition to the MOSFET) to the display PWB are needed to implement a low power mode single LED control. Another technical effect of one or more of the example embodiments disclosed herein is that no additional control line(s) for the LED driver are needed. Another technical effect of one or more of the example embodiments disclosed herein is that no additional pin on a connector is needed. Another technical effect of one or more of the example embodiments disclosed herein is that the LED drivers can perform this functionality. Another technical effect of one or more of the example embodiments disclosed herein is that the display module can use this functionality in the same way even if this functionality is implemented on the display modules, and this functionality can be started for use later (SW issue). Another technical effect of one or more of the example embodiments disclosed herein is that this functionality could be implemented any suitable display module, then depending if the phone program uses the function or not, they can enable only one branch of the LED driver and easily enter to low power mode. Additionally, this functionality enables to use existing display driver ICs without any time taking HW changes.

According to various exemplary embodiments of the invention, improved picture quality can be provided by operating the display module 38 in an impulse mode (as opposed to a continuous mode), where the backlight unit is turned on and off. The backlight unit, when operating in the impulse mode, generally outputs higher brightness (by providing a higher driving current, for example) than when the backlight unit is always on, such as in the continuous mode where a lower driving current is generally provided. Accordingly, ambient temperatures are generally higher in the impulse mode than in the continuous mode. Therefore, according to some embodiments of the invention, the ambient temperature of the LEDs can be measured in the impulse mode by a temperature sensor and the driving current of the LEDs can be adjusted so that the LEDs are not damaged (such as preventing damage from being out of the maximum range, for example).

Referring now also to FIG. 15, there is shown a schematic drawing of an example backlight LED connection configuration (or backlight arrangement) 200 according to another example of the invention. The backlight LED connection configuration 200 is similar to the backlight LED connection configuration 100 and similar features are similarly numbered. However, in this embodiment the LED connection configuration 200 is configured for temperature measurement of the display backlight.

The backlight LED connection configuration 200 includes the LED driver 42, the LEDs 111, 112, 121, 122, and the switch 106. However, in this embodiment the backlight LED connection configuration 200 includes a temperature sensor 230 (which may be a thermistor, for example), wherein the switch 106 and the temperature sensor 230 are connected in parallel with the light sources. Similarly, this configuration can provide for changing a configuration of the light sources to change illumination of the backlight of the LCD panel, or keyboard.

Still referring to FIG. 15, the switch 106 and the temperature sensor (or component) 230 are connected in parallel with light sources 121, 122, and are connected between the second output 104 of the LED driver 42 and ground (GND). In this embodiment, the switch 106 is controlled by the first output pin 102 of the LED driver 42. Additionally, the second output pin 104 of the LED driver 42 is also connected to an input block of the LED driver 42 that can measure the second output pin 104 voltage level.

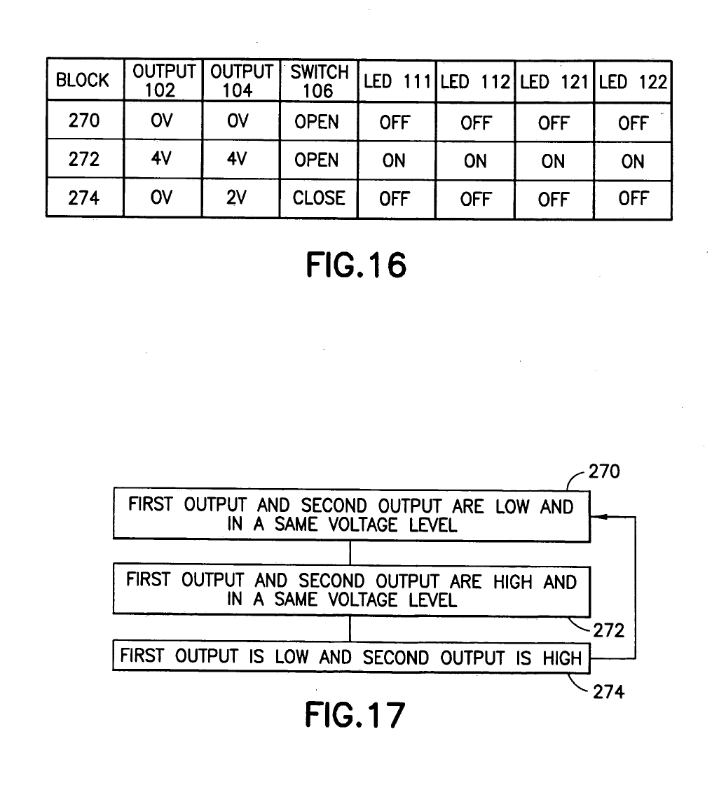

In this embodiment, various sequences may be provided, for example, and referring also to FIGS. 16-17, the sequence includes: the first output 102 and the second output 104 are low and in a same voltage level, the LEDs (or components) 111, 112, 121, 122 are off and the switch 106 is open (at block 270). The first output 102 and the second output 104 are high and in same voltage level: LEDs 111, 112, 121, 122 are on and the switch 106 is open (at block 272). The first output 102 is low and the second output 104 is high (the second output 104 is higher than the first output 102, wherein the second output 104 is 2V, which is lower than LEDs forward voltage of 3.2V): the LEDs 111, 112, 121, 122 are off and the switch 106 is closed. The temperature sensor 230 is connected to the second output 104 and it is dropping the second output 104 voltage (start level 2V) that is equal ambient temperature of the LEDs (at block 274). After block 274, the sequence may return back to block 270.

According to some embodiments of the invention, the LED driver 42 can adjust the current at the first output pin 102 and the second output pin 104 for the LEDs based on the temperature measurement result of block 274.

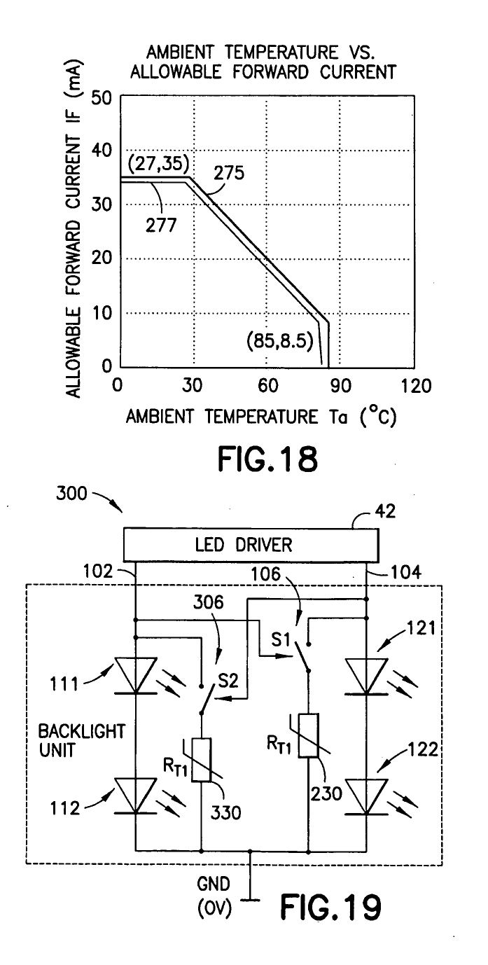

Referring now also to FIG. 18, there is shown a graphical representation of the current and temperature for the LEDs. The line 275 shows an example of how a maximum continuous forward current of the LED may depend on ambient temperature. Line 277 shows an example of the LED current (the first output 102 and the second output 104) in impulse mode or continuous mode.

In some embodiments of the invention, the sequence can be used for each refreshed display frame in the impulse mode (wherein the backlight may also be off). Additionally, the sequence can be used time-to-time in a continuous mode.

It should also be noted that in other embodiments, any suitable type of component, such as the device engine, for example, can be provided to measure the second output pin 104 voltage level, without using the LED driver 42. However, any suitable configuration may be provided.

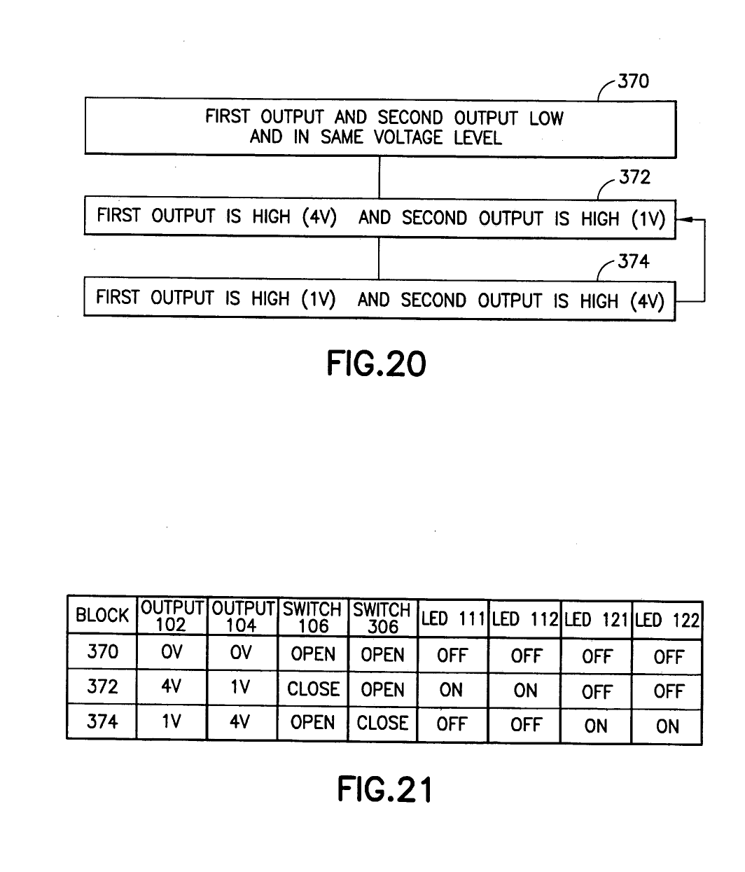

According to some embodiments of the invention, a method substantially similar to the method above can also be used for scanning backlights when an additional switch 306 and an additional temperature sensor 330 are added to the backlight arrangement (see FIG. 19). For example, an exemplary sequence for scanning backlights (with the backlight arrangement 300) may be provided as follows (see FIGS. 20, 21): the first output 102 and the second output 104 are low and in same voltage level: the LEDs 111, 112, 121, 122 are off and the switches 106, 306 are open (370). The first output 102 is high (4V) and the second output 104 is high (1V): LEDs 111 and 112 are on and LEDs 121 and 122 are off; the switch 106 is closed and the switch 306 is open, then the LED driver can measure a voltage drop via the second output 104 with the temperature sensor 230 value of the LEDs 121 and 122 (block 372). The first output 102 is high (1V) and the second output 104 is high (4V): the LEDs 111, 112 are off and the LEDs 121, 122 are on; the switch 306 is closed and the switch 106 is open, then the LED driver 42 can measure a voltage drop via the first output 102 with the temperature sensor 330 value of the LEDs 111, 112 (block 374). After block 374, the sequence can return to block 372.

The current and temperature profile for the LED shown in FIG. 18 also applies for the scanning backlight configuration, wherein the line 277 shows an example of the LED current (the first output 102 and the second output 104) in the impulse mode with a scanning backlight mode.

It should be noted that although various exemplary embodiments described above (such as the embodiments shown in FIGS. 15, 19, for example) comprise the switch 106, 306, some embodiments of the invention could perform the temperature measurement without the switch 106, 306. For example, if voltage 102 or 104 rises slightly but not above 2× LED voltage drop=2×Vf, then current will flow through the temperature sensor, relative to ambient temperature. However, it should be noted that with this type of configuration, isolation of the temperature sensor may not be possible.

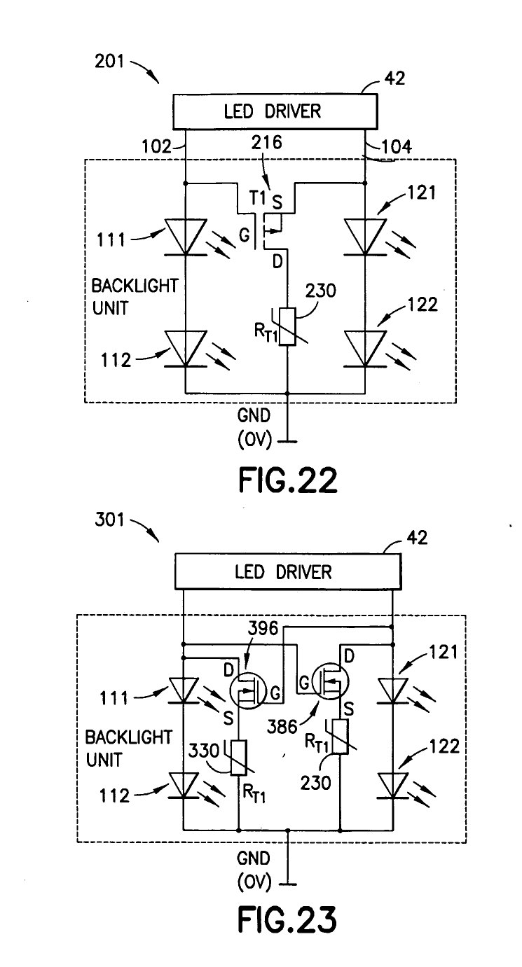

Referring now also to FIG. 22, there is shown a schematic drawing of an example backlight LED connection configuration 201 according to another example of the invention. The backlight LED connection configuration 201 is similar to the backlight LED connection configuration 200 and similar features are similarly numbered. The backlight LED connection configuration 201 includes the LED driver 42, the LEDs 111, 112, 121, 122, and the temperature sensor 230. However, in this embodiment the switch is replaced with a p-type MOSFET Transistor 216. The configuration table shown in FIG. 16 also similarly applies for the backlight arrangement 201 (wherein the switch values would correspond to a switch portion of the transistor 216). Similarly, the backlight arrangement 201 can provide for changing a configuration of the light sources to change illumination of the backlight of the LCD panel, or keyboard.

While various exemplary embodiments of the invention have been described above in connection with a p-type metal-oxide-semiconductor field-effect transistor (MOSFET), one skilled in the art will appreciate various exemplary embodiments of the invention are not necessarily so limited and that other types of metal-oxide-semiconductor field-effect transistors may be provided. For example an n-type MOSFET (NMOS) could generally be utilized if the Vgs is high enough. According to some embodiments of the invention, and where circuit voltages are selected for MOSFET control, the MOSFET could be also an NMOS if the voltage in output 104 is generally significantly higher than the voltage at an anode of LED 122 (this is generally the case if the output 102 has more LEDs connected in series than the output 104). Additionally, it should further be noted that any other suitable switch types, such as traditional NPN or PNP transistors for example, could also be provided.

Referring now also to FIG. 23, there is shown a schematic drawing of an example backlight LED connection configuration (or backlight arrangement) 301 according to another example of the invention. The backlight LED connection configuration 301 is similar to the backlight LED connection configuration 300, and similar features are similarly numbered. The backlight LED connection configuration 301 includes the LED driver 42, the LEDs 111, 112, 121, 122, and the temperature sensors 230, 330. However, in this embodiment the switches 106, 306 are replaced with n-type MOSFET Transistors 386, 396. The configuration table shown in FIG. 21 also similarly applies for the backlight arrangement 301 (wherein the switch values would correspond to a switch portion of the transistors 386, 396). It should be noted that for dual backlight application, it is clear for one skilled in the art, that the use of NMOS transistors is justified in this case. Moreover, one must consider that enough Vgs voltage difference must be given to the NMOS switch for it to be able to function as a so called high side switch. In other words, a voltage drop in the temperature sensor 230 and 330 must be so small that Vgs exceeds the transistor specific turn-on threshold. Use of a PMOS may lead to more difficult temperature measurement and different on/off states in table of FIG. 21. Similar to the backlight arrangement 300, the backlight arrangement 301 can provide a scanning backlight configuration.

It should be noted that the scanning backlight examples described above may be considered somewhat of a special case. For example, in the “non-scanning” backlight configurations (such as the configurations in FIGS. 15, 22 for example) the LED chain 111, 112 generally has the output 102 or 104 below the level of LED forward voltage drop Vf (or 2*Vf in these examples). However, the scanning backlight configurations (such as the configurations in FIGS. 19, 23 for example) generally switch one of the LED chains on while the other of the LED chains is being measured. Therefore, according to some embodiments of the invention the transistor configuration comprises an NMOS field-effect transistor (as in FIG. 23), as it may be substantially difficult to measure temperature in the particular chain that has LEDs “on” when using a PMOS field-effect transistor.

According to some embodiments of the invention, the NMOS source voltage will become V(Rt 230 or 330). Thus, Vgate generally needs to be >Vth (NMOS)+V(Rt) to turn the NMOS transistor on. Thus, this configuration may be limited only to higher number of LEDs, in which NMOS Vgs becomes high enough for the transistor to turn on. However, any suitable configuration may be provided.

Technical effects of any one or more of the exemplary embodiments provide advantages over conventional configurations which include additional measurement lines to measure an ambient temperature of the light sources via a temperature sensor (RT), as these extra lines generally require more space on a device design, such as additional pins on connectors, or more lines on flex, for example.

Further technical effects of any one or more of the exemplary embodiments provide advantages over conventional configurations. For example when LEDs are driven in impulse, the temperature of the LEDs tend to get higher than in continuous mode. To enable lower temperature, the continuous mode needs to be improved to allow more brightness levels. Technical effects of any one or more of the exemplary embodiments provide a feedback loop from a temperature sensor to LED drivers so that the temperature measurement components enable or disable how many LEDs are used at a time in switch mode LED circuitry.

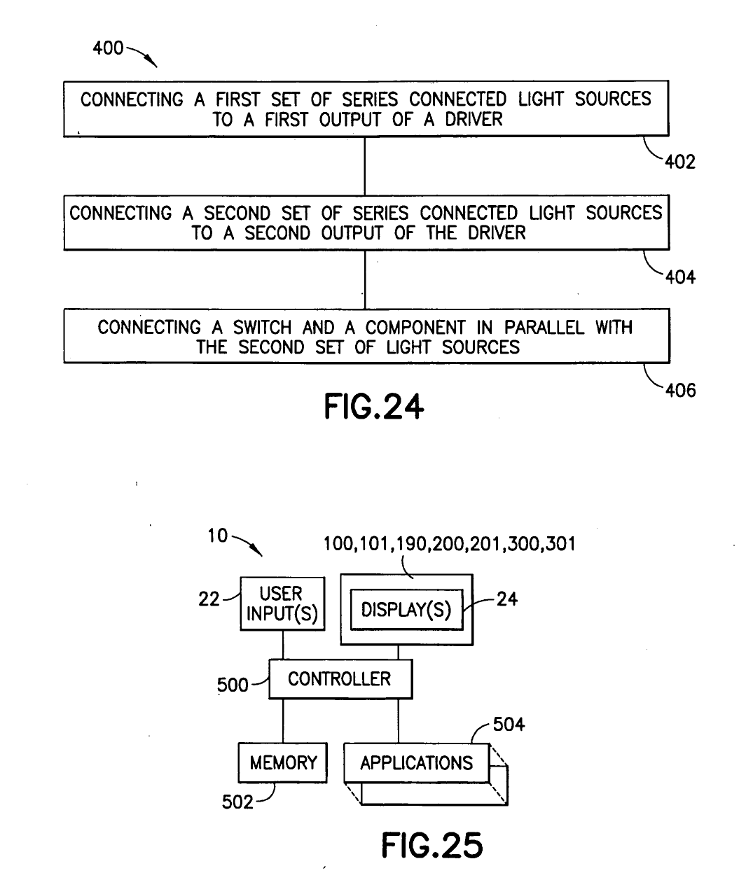

FIG. 24 illustrates a method 400. The method 400 includes connecting a first set of series connected light sources to a first output of a driver (at block 402). Connecting a second set of series connected light sources to a second output of the driver (at block 404). Connecting a switch and a component in parallel with the second set of light sources, wherein the switch is configured to be controlled by the first output of the driver, and wherein the temperature sensor is connected to the second output of the driver (at block 406). The component may be any suitable component such as (but not limited to) a temperature sensor. It should be noted that the illustration of a particular order of the blocks does not necessarily imply that there is a required or preferred order for the blocks and the order and arrangement of the blocks may be varied. Furthermore it may be possible for some blocks to be omitted.

Referring now also to FIG. 25, the device 10 generally comprises a controller 500 such as a microprocessor for example. The electronic circuitry includes a memory 502 coupled to the controller 500, such as on a printed circuit board for example. The memory could include multiple memories including removable memory modules for example. The device has applications 504, such as software, which the user can use. The applications can include, for example, a telephone application, an Internet browsing application, a game playing application, a digital camera application, a map/gps application, etc. These are only some examples and should not be considered as limiting. One or more user inputs 22 are coupled to the controller 500 and one or more displays 24 are coupled to the controller 500. The backlight arrangement 100, 101, 190, 200, 201, 300, 301 is also coupled to the controller 500. The device 10 may be programmed to automatically energize and de-energize an LED arrangement in an impulse mode, for example.

Although various examples of the invention described above use 4V as example for LED drive, it should be noted that this is merely provided as a non-limiting example, and any suitable LED voltage may be provided. For example, many LEDs can have significantly higher Vf such as 3.5V, causing 2×Vf to be 7V.

It should further be noted that although various examples of the invention described above are described in connection with two series LEDs, this is not required, and any suitable number of series LEDs can be provided.

Without in any way limiting the scope, interpretation, or application of the claims appearing below, a technical effect of one or more of the example embodiments disclosed herein is providing a backlight arrangement wherein an additional line for LED driver is not required. Another technical effect of one or more of the example embodiments disclosed herein is providing a backlight arrangement wherein an additional pin on a connector is not required. Another technical effect of one or more of the example embodiments disclosed herein is providing LED drivers which can perform the temperature measurement functionality or providing another component which can measure temperature. Another technical effect of one or more of the example embodiments disclosed herein is that the backlight arrangement can support scanning backlight modes. Another technical effect of one or more of the example embodiments disclosed herein is that the backlight arrangement can offer a backlight control for display, or keyboard, without an extra line with maximum brightness over temperature range.

It should be understood that components of the invention can be operationally coupled or connected and that any number or combination of intervening elements can exist (including no intervening elements). The connections can be direct or indirect and additionally there can merely be a functional relationship between components.

As used in this application, the term ‘circuitry’ refers to all of the following: (a) hardware-only circuit implementations (such as implementations in only analog and/or digital circuitry) and (b) to combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions) and (c) to circuits, such as a microprocessor(s) or a portion of a microprocessor(s), that require software or firmware for operation, even if the software or firmware is not physically present.

This definition of ‘circuitry’ applies to all uses of this term in this application, including in any claims. As a further example, as used in this application, the term “circuitry” would also cover an implementation of merely a processor (or multiple processors) or portion of a processor and its (or their) accompanying software and/or firmware. The term “circuitry” would also cover, for example and if applicable to the particular claim element, a baseband integrated circuit or applications processor integrated circuit for a mobile phone or a similar integrated circuit in server, a cellular network device, or other network device.

Embodiments of the present invention may be implemented in software, hardware, application logic or a combination of software, hardware and application logic. The software, application logic and/or hardware may reside on the device or a server. If desired, part of the software, application logic and/or hardware may reside on the device, and part of the software, application logic and/or hardware may reside on the server. In an example embodiment, the application logic, software or an instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computer, with one example of a computer described and depicted in FIG. 25. A computer-readable medium may comprise a computer-readable storage medium that may be any media or means that can contain or store the instructions for use by or in connection with an instruction execution system, apparatus, or device, such as a computer.

If desired, the different functions discussed herein may be performed in a different order and/or concurrently with each other. Furthermore, if desired, one or more of the above-described functions may be optional or may be combined.

Below are provided further descriptions of various non-limiting, exemplary embodiments. The various aspects of one or more exemplary embodiments may be practiced in conjunction with one or more other aspects or exemplary embodiments. That is, the exemplary embodiments of the invention, such as those described immediately below, may be implemented, practiced or utilized in any combination (e.g., any combination that is suitable, practicable and/or feasible) and are not limited only to those combinations described herein and/or included in the appended claims.

In one exemplary embodiment, a backlight arrangement for configurable Light Emitting Diode (LED) driving selection circuit without an additional control line. The LEDs are configured as different number of parallel chains. A Field Effect Transistor (FET) acting as a switch is connected in parallel with a LED(s) of one of the parallel chains. This switch can be controlled by driving outputs of other parallel chain of LEDs. This switch, in the closed state, will bypass the light source.

In another exemplary embodiment, a method of temperature measurement on display backlight. The backlight unit is turned on and off in an impulse mode. The backlight unit needs to output higher brightness in impulse mode. An ambient temperature is higher in impulse mode than in continuous mode. The ambient temperature of the light emitting diodes (LEDs) is measured in impulse mode by a temperature sensor. LEDs (Light sources) are connected in serial and parallel chains. A switch (P-type MOSFET) and a temperature sensor are connected in parallel with light sources (LEDs). The switch is controlled by the LED driver's first output. The LED driver's first output is connected to the pair of LEDs which are in series. The second output of the LED driver is connected to an input block of the LED driver to measure the second output voltage level. When the first and second output voltages are low then LEDs are off and the switch is open. When they are high and in same voltage level the LEDs are on and the switch is open. When the first output is low and the second output is high then the LEDs are off and the switch is closed. The temperature sensor is connected to second output and it is dropping the second voltage what is equal ambient temperature of the LEDs. The LED driver is adjusting the first output and second output currents for LEDs according to the temperature measurement result. Further, the sequence can be used for each refreshed display frame in impulse mode as the backlight is off. The switch (P-type MOSFET) and the temperature sensor are connected in parallel with light sources (LEDs). The switch is controlled by the LED driver's first output. The LED driver is adjusting the output currents for LEDs according to the temperature measurement result.

In another exemplary embodiment, an apparatus comprising a driver, a set of first components, a set of second components, a third component, and a switch. The driver includes a first output and a second output. The set of first components is connected to the first output of the driver, wherein the set of first components are connected in series. The set of second components is connected to the second output of the driver, wherein the set of second components are connected in series. The third component is connected in parallel with the set of second components. The switch is connected in parallel with the set of second components, wherein the switch is between the third component and the second output of the driver, and wherein the switch is configured to be controlled by the first output of the driver.

An apparatus as above, wherein the set of first components comprises at least two light emitting diodes.

An apparatus as above, wherein the set of second components comprises at least two light emitting diodes.

An apparatus as above, wherein the switch is a p-type or n-type metal-oxide-semiconductor field-effect transistor.

An apparatus as above, wherein the third component comprises a temperature sensor, wherein the temperature sensor is configured to provide a feedback loop to the driver, and wherein the driver is configured to adjust an output current at the first output and/or the second output based on a sensed temperature of the temperature sensor.

An apparatus as above, wherein the driver comprises a light emitting diode driver.

An apparatus as above, wherein the set of first components and the set of second components are configured to be operated in an impulse mode.

An apparatus as above, wherein the switch is configured to be actuated without an additional control line between the switch and the driver.

An apparatus as above, further comprising another switch and a fourth component, wherein the another switch is connected in parallel with the set of first components, wherein the another switch is between the fourth component and the first output of the driver, and wherein the another switch is configured to be controlled by the second output of the driver.

A device comprising a display and an apparatus as above connected to the display.

In another exemplary embodiment, an apparatus comprising an electronic component, at least two light sources, a switch, and a temperature sensor. The at least two light sources are connected to the electronic component, wherein a first one of the at least two light sources is connected in parallel with a second one of the at least two light sources. The switch is connected in parallel with the second one of the at least two light sources, wherein the switch is configured to be controlled by the electronic component. The temperature sensor is connected in parallel with the second one of the at least two light sources, wherein the temperature sensor is configured to provide a feedback loop to the electronic component, and wherein the electronic component is configured to adjust an output current at the at least two light sources based on a sensed temperature of the temperature sensor.

An apparatus as above, wherein the light sources are light emitting diodes.

An apparatus as above, wherein the switch is a p-type or n-type metal-oxide-semiconductor field-effect transistor.

An apparatus as above, wherein the electronic component is a light emitting diode driver, and wherein the driver comprises a first output and a second output.

An apparatus as above, wherein the first output of the driver is configured to control the switch, and wherein the second output of the driver is configured to be connected to the temperature sensor.

An apparatus as above, wherein the first one of the at least two light sources is connected to the first output, and wherein the second one of the at least two light sources is connected to the second output.

An apparatus as above, wherein the light sources are configured to be operated in an impulse mode.

An apparatus as above, wherein the apparatus further comprises a third light source connected in series with the first one of the at least two light sources, and a fourth light source connected in series with the second one of the at least two light sources.

An apparatus as above, wherein the switch and the temperature sensor are connected to an output of the electronic component, and wherein the fourth light source and the second one of the at least two light sources are connected to the same output of the driver.

A device comprising a display and an apparatus as above connected to the display.

In another exemplary embodiment, a method is disclosed, comprising connecting a first set of series connected light sources to a first output of a driver. Connecting a second set of series connected light sources to a second output of the driver. Connecting a switch and a component in parallel with the second set of light sources, wherein the switch is configured to be controlled by the first output of the driver, and wherein the component is connected to the second output of the driver.

A method as above, wherein the light sources comprise light emitting diodes.

A method as above, wherein the switch comprises a p-type or n-type metal-oxide-semiconductor field-effect transistor.

A method as above, wherein the component is connected to the driver without an additional control line therebetween.

A method as above, wherein the component comprises a temperature sensor, and wherein the driver is configured to adjust output currents for the light sources in response to a temperature measurement of the temperature sensor.

A method as above, further comprising connecting another switch and another temperature sensor in parallel with the first set of light sources, wherein the another switch is configured to be controlled by the second output of the driver, and wherein the another temperature sensor is connected to the first output of the driver.

In another exemplary embodiment, a method is disclosed, comprising connecting a first set of series connected light sources to a first output of a driver. Connecting a second set of series connected light sources to a second output of the driver. Connecting a switch and a temperature sensor in parallel with the second set of light sources, wherein the switch is configured to be controlled by the first output of the driver, and wherein the temperature sensor is connected to the second output of the driver.

A method as above, wherein the driver is configured to adjust output currents for the light sources in response to a temperature measurement of the temperature sensor.

A method as above, wherein the light sources comprise light emitting diodes.

A method as above, wherein the switch comprises a p-type or n-type metal-oxide-semiconductor field-effect transistor, and wherein the temperature sensor comprises a thermistor.

A method as above, wherein the temperature sensor is connected to the driver without an additional measurement line therebetween.

A method as above, further comprising connecting another switch and another temperature sensor in parallel with the first set of light sources, wherein the another switch is configured to be controlled by the second output of the driver, and wherein the another temperature sensor is connected to the first output of the driver.

In another exemplary embodiment, an apparatus comprising at least one processor and at least one memory including computer program code. The at least one memory and the computer program code configured to, with the at least one processor, cause the apparatus to perform at least the following: control a switch with a first output of a driver. Adjust output currents at the first output of the driver and a second output of the driver in response to a measurement of a temperature sensor, wherein the temperature sensor is connected to the second output of the driver. Energize a first set and a second set of light sources in an impulse mode, wherein the first set of light sources is connected to the first output, and wherein the second set of light sources is connected to the second output.

An apparatus as above, wherein the first set of light sources are connected in series, wherein the second set of light sources are connected in series, and wherein the switch and the temperature sensor are connected in parallel with the second set of light sources.

An apparatus as above, wherein the temperature sensor is connected to driver without an additional measurement line.

An apparatus as above, wherein the driver is connected to the at least one processor.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

1. An apparatus, comprising:
a driver comprising a first output and a second output;
a set of first components connected to the first output of the driver, wherein the set of first components are connected in series;
a set of second components connected to the second output of the driver, wherein the set of second components are connected in series;
a third component connected in parallel with the set of second components; and
a switch connected in parallel with the set of second components, wherein the switch is between the third component and the second output of the driver, and wherein the switch is configured to be controlled by the first output of the driver.

2. An apparatus as in claim 1 wherein the set of first components comprises at least two light emitting diodes.

3. An apparatus as in claim 1 wherein the set of second components comprises at least two light emitting diodes.

4. An apparatus as in claim 1 wherein the switch is a p-type or n-type metal-oxide-semiconductor field-effect transistor.

5. An apparatus as in claim 1 wherein the third component comprises a temperature sensor, wherein the temperature sensor is configured to provide a feedback loop to the driver, and wherein the driver is configured to adjust an output current at the first output and/or the second output based on a sensed temperature of the temperature sensor.

6. An apparatus as in claim 1 wherein the driver comprises a light emitting diode driver.

7. An apparatus as in claim 1 wherein the set of first components and the set of second components are configured to be operated in an impulse mode.

8. An apparatus as in claim 1 wherein the switch is configured to be actuated without an additional control line between the switch and the driver.

9. An apparatus as in claim 1 further comprising another switch and a fourth component, wherein the another switch is connected in parallel with the set of first components, wherein the another switch is between the fourth component and the first output of the driver, and wherein the another switch is configured to be controlled by the second output of the driver.

10. A device comprising:
a display; and
an apparatus as in claim 1 connected to the display.

11. A method, comprising:
connecting a first set of series connected light sources to a first output of a driver;
connecting a second set of series connected light sources to a second output of the driver; and
connecting a switch and a component in parallel with the second set of light sources, wherein the switch is configured to be controlled by the first output of the driver, and wherein the component is connected to the second output of the driver.

12. A method as in claim 11 wherein the light sources comprise light emitting diodes.

13. A method as in claim 11 wherein the switch comprises a p-type or n-type metal-oxide-semiconductor field-effect transistor.

14. A method as in claim 11 wherein the component is connected to the driver without an additional control line therebetween.

15. A method as in claim 11 wherein the component comprises a temperature sensor, and wherein the driver is configured to adjust output currents for the light sources in response to a temperature measurement of the temperature sensor.

16. A method as in claim 15 further comprising connecting another switch and another temperature sensor in parallel with the first set of light sources, wherein the another switch is configured to be controlled by the second output of the driver, and wherein the another temperature sensor is connected to the first output of the driver.

17. An apparatus, comprising:
at least one processor; and
at least one memory including computer program code
the at least one memory and the computer program code configured to, with the at least one processor, cause the apparatus to perform at least the following:
control a switch with a first output of a driver;
adjust output currents at the first output of the driver and a second output of the driver in response to a measurement of a temperature sensor, wherein the temperature sensor is connected to the second output of the driver; and
energize a first set and a second set of light sources in an impulse mode, wherein the first set of light sources is connected to the first output, and wherein the second set of light sources is connected to the second output.

18. An apparatus as in claim 17 wherein the first set of light sources are connected in series, wherein the second set of light sources are connected in series, and wherein the switch and the temperature sensor are connected in parallel with the second set of light sources.

19. An apparatus as in claim 17 wherein the temperature sensor is connected to driver without an additional measurement line.

20. An apparatus as in claim 17 wherein the driver is connected to the at least one processor.
